(19) United States
(12) Patent Application Publication
(10) Pub. No.: US 2022/0254718 A1
(43) Pub. Date: Aug. 11, 2022

(54) METHOD FOR FUSING AND FILLING SEMICONDUCTOR STRUCTURE, AND SEMICONDUCTOR STRUCTURE

(71) Applicant: CHANGXIN MEMORY TECHNOLOGIES, INC., Hefei City (CN)

(72) Inventor: Guangcai GONG, Hefei City (CN)

(73) Assignee: CHANGXIN MEMORY TECHNOLOGIES, INC., Hefei City (CN)

(21) Appl. No.: 17/649,165

(22) Filed: Jan. 27, 2022

Related U.S. Application Data
(63) Continuation of application No. PCT/CN2021/109303, filed on Jul. 29, 2021.

(30) Foreign Application Priority Data
Feb. 7, 2021 (CN) 202110177190.4

(51) Int. Cl. H01L 23/525; H01L 23/10; H01L 21/54

(52) U.S. Cl. CPC H01L 23/5258; H01L 21/54; H01L 23/10

(57) ABSTRACT

A method for fusing and filling a semiconductor structure includes: a semiconductor structure body is provided, a plurality of fuse array groups is formed in the semiconductor structure body; at least one of interconnection structures of the fuse array groups is fused to form at least one notch in the semiconductor structure body; a shielding layer is formed on the semiconductor structure body, at least one through hole exposing the at least one notch is formed in the shielding layer; and a sealing material layer is formed in the notch.

### CROSS-REFERENCE TO RELATED APPLICATIONS

This is a continuation of International Application No. PCT/CN2021/109303 filed on Jul. 29, 2021, which claims priority to Chinese patent application No. 202110177190.4 filed on Feb. 7, 2021. The disclosures of these applications are hereby incorporated by reference in their entirety.

### BACKGROUND

Multiple fuse array groups are formed in a semiconductor structure. In the process of testing, if there are problems with a part of the fuse array groups, the back-end interconnection line may be blown by means of the laser high temperature to change a connection structure. After the back-end interconnection line is blown, a notch will be formed in the semiconductor structure. The notch is not protected, which results in external interference on a back-end interconnection side surface formed after the blowing, thereby affecting the service performance of the semiconductor structure.

### SUMMARY

The disclosure relates to the field of semiconductor technologies, and provides a method for fusing and filling a semiconductor structure, and the semiconductor structure.

According to the first aspect of the disclosure, a method for fusing and filling a semiconductor structure is provided, which may include the following operations.

A semiconductor structure body is provided. Multiple fuse array groups are formed in the semiconductor structure body.

At least one of interconnection structures of the fuse array groups is fused to form at least one notch in the semiconductor structure body.

A shielding layer is formed on the semiconductor structure body. At least one through hole exposing the at least one notch is formed in the shielding layer.

A sealing material layer is formed in the notch.

According to the second aspect of the disclosure, a semiconductor structure is provided, which may include a semiconductor structure body and a sealing material layer.

Multiple fuse array groups are formed in the semiconductor structure body, at least one notch is formed in the semiconductor structure body, and at least one of interconnection structures of the fuse array groups is fused.

The sealing material layer is located in the notch.

### BRIEF DESCRIPTION OF THE DRAWINGS

The various objects, features and advantages of the disclosure will become more apparent by considering the following detailed description of preferred implementation modes of the disclosure in combination with the drawings. The drawings are only exemplary illustrations of the disclosure, and are not necessarily drawn to scale. In the drawings, the same drawing signs always represent the same or similar parts.

FIG. 1 is a schematic flowchart of a method for fusing and filling a semiconductor structure according to an exemplary implementation.

FIG. 2 is a schematic structural diagram of a semiconductor structure body according to an exemplary implementation.

FIG. 3 is an enlarged schematic structural diagram at a position A in FIG. 2.

FIG. 4 is a schematic structural diagram of a semiconductor structure body covered with a shielding layer according to an exemplary implementation.

FIG. 5 is a schematic structural diagram of a semiconductor structure body covered with a shielding layer according to another exemplary implementation.

FIG. 6 is a schematic structural diagram of a second positioning part formed in a semiconductor structure body according to an exemplary implementation.

FIG. 7 is a schematic structural diagram of a shielding layer formed on a semiconductor structure body according to an exemplary implementation.

FIG. 8 is a schematic structural diagram of an opening formed by a method for fusing and filling a semiconductor structure according to an exemplary implementation.

FIG. 9 is a schematic structural diagram of a notch formed by a method for fusing and filling a semiconductor structure according to an exemplary implementation.

FIG. 10 is a schematic structural diagram of a shielding layer formed by a method for fusing and filling a semiconductor structure according to an exemplary implementation.

FIG. 11 is a schematic structural diagram of an initial sealing material layer formed by a method for fusing and filling a semiconductor structure according to an exemplary implementation.

FIG. 12 is a schematic structural diagram after a shielding layer is removed by a method for fuse and filling a semiconductor structure according to an exemplary implementation.

FIG. 13 is a schematic structural diagram after an initial sealing material layer is cleaned by a method for fusing and filling a semiconductor structure according to an exemplary implementation.

FIG. 14 is a schematic structural diagram of a sealing material layer formed by a method for fusing and filling a semiconductor structure according to an exemplary implementation.

### DESCRIPTION OF THE SIGNS IN THE DRAWINGS IS AS FOLLOWS

1. Die; 10. Semiconductor structure body; 11. Notch; 12. Wafer notch; 13. Opening; 14. Substrate; 15. Wafer positioning identifier; 20. Fuse array group; 21. Interconnection structure; 22. Bonding pad; 23. Contact hole; 30. Shielding layer; 31. Through hole; 32. Film positioning hole; 33. Film positioning identifier; 40. Sealing material layer; 41. Initial sealing material layer; and 50. Seal ring.

### DETAILED DESCRIPTION

Typical embodiments embodying the features and advantages of the disclosure will be described in detail in the following description. It should be understood that the disclosure may have various changes in different embodiments, which do not depart from the scope of the disclosure, and the description and drawings therein are essentially for illustration rather than to limit the disclosure.

The following descriptions of different exemplary implementations of the disclosure are carried out with reference to the drawings. The drawings are a part of the disclosure. Moreover, different exemplary structures, systems and operations capable of realizing a plurality of aspects of the disclosure are displayed in an exemplary manner. It is to be understood that other specific schemes of parts, structures, exemplary devices, systems and operations may be used, and moreover, structural and functional modification may be carried out without departing from the scope of the disclosure. Moreover, although terms such as “above”, “between” and “in” may be used herein for describing different exemplary features and components of the disclosure, these terms are used herein for convenience only, such as according to directions of examples in the drawings. Nothing in the description should be understood as requiring a specific three-dimensional orientation of a structure in order to fall within the scope of the disclosure.

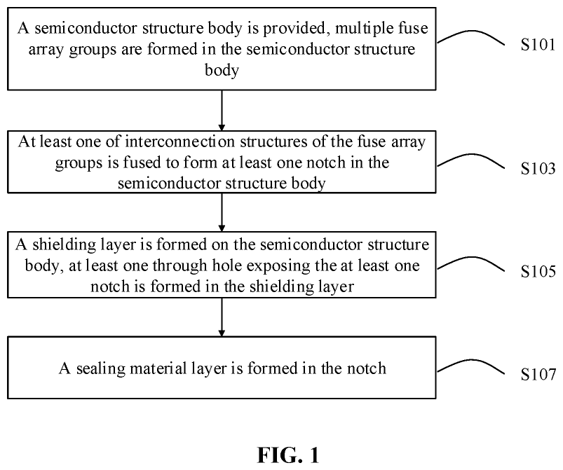

An embodiment of the disclosure provides a method for fusing and filling a semiconductor structure. With reference to FIG. 1, the method for fusing and filling the semiconductor structure may include the following operations.

At S101, a semiconductor structure body 10 is provided, multiple fuse array groups 20 are formed in the semiconductor structure body 10.

At S103, at least one of interconnection structures 21 of the fuse array groups 20 is fused to form at least one notch 11 in the semiconductor structure body 10.

At S105, a shielding layer 30 is formed on the semiconductor structure body 10, at least one through hole 31 exposing the at least one notch 11 is formed in the shielding layer 30.

At S107, a sealing material layer 40 is formed in the notch 11.

According to the method for fusing and filling the semiconductor structure of an embodiment of the disclosure, the shielding layer 30 is formed on the semiconductor structure body 10 with the notch 11, and furthermore, the through hole 31 exposing the notch 11 is formed in the shielding layer 30, so that during subsequent filling of the notch 11, the sealing material layer 40 will not directly cover the semiconductor structure body 10 in a large area due to the existence of the shielding layer 30, which avoids subsequent cleaning, and may ensure the reliable formation of the sealing material layer 40 in the notch 11, so as to isolate the invasion of external risk factors and improve the service performance of the semiconductor structure.

It is to be noted that when a Dynamic Random Access Memory (DRAM) is found to have fail capacitors, fail word lines, fail bit lines and/or the like after being tested, in a related art, these fail bits will be repaired by fusing through a fuse. The process is to change the structure of a connection line and connect the connection line to redundancy bits to replace the fail bits, so as to achieve the repairing effect.

In some embodiments, a back-end interconnection line (i.e. an interconnection structure 21 of a fuse array group 20) is blown by means of laser high temperature, to change a connection structure. When the interconnection structure 21 of the fuse array group 20 is blown, a notch 11 will be formed. If the notch 11 is not protected, a back-end interconnection side surface formed after the blowing (fusing) will become an intrusion port of external moisture, impurity metal ions and even external static electricity and stress, which will weaken the material strength and dielectric effect of a back-end interconnection dielectric layer, and finally lead to structural delamination, crack, electric leakage, deterioration of device performance, low reliability, thereby affecting bonding, and product use and the like. In the embodiment, the above problem may be avoided by forming the sealing material layer 40 in the notch 11.

It should be noted that the shielding layer 30 formed on the semiconductor structure body 10 is configured to prevent the sealing material layer 40 from being formed in some areas of the semiconductor structure body 10. For example, it may happen that the sealing material layer 40 may cover bonding pad(s) of the semiconductor structure body 10, and the sealing material layer 40 needs to be removed in the subsequent process. Since the sealing material layer 40 is difficult to be removed due to the material and structural limitations of the sealing material layer 40, the bonding pad(s) may be damaged in serious cases, thereby affecting bonding. In the embodiment, the arrangement of the shielding layer 30 may avoid the above problems and ensure that the sealing material layer 40 will not cover the position that should not be covered.

In some embodiments, the fuse array group 20 may include an interconnection structure 21, a bonding pad 22 and a contact hole 23. The interconnection structure 21 is connected to the bonding pad 22 and the contact hole 23. The bonding pad 22 may be a bonding aluminum pad, and the contact hole 23 may be connected to a substrate 14 of the semiconductor structure body 10. The specific structure of the fuse array group 20 is not limited here, and may be various fuse array groups of semiconductor structures formed in the related art.

In an embodiment, the shielding layer 30 is made of a hard material. That is, the shielding layer 30 has a certain hardness, so as to ensure that there will be no damage, avoid the problem of weakening the protective performance and also facilitate the subsequent removal of the shielding layer 30.

In an embodiment, the shielding layer 30 is made of a polymer material, ceramic or a metal material to ensure that the shielding layer 30 has a certain strength.

It should be noted that the shielding layer 30 belongs to a protective structure and will be removed in subsequent process, and the shielding layer 30 made of the hard material is also easy to be removed, so as to improve the formation efficiency.

In an embodiment, the sealing material layer 40 may be an epoxy resin material or a polyimide resin material.

In an embodiment, multiple fuse array groups 20 are fused to form multiple independent notches 11 in the semiconductor structure body 10. In some cases, there will be problems with the multiple fuse array groups 20. In this state, the multiple fuse array groups 20 need to be fused, so that the multiple independent notches 11 are formed in the semiconductor structure body 10.

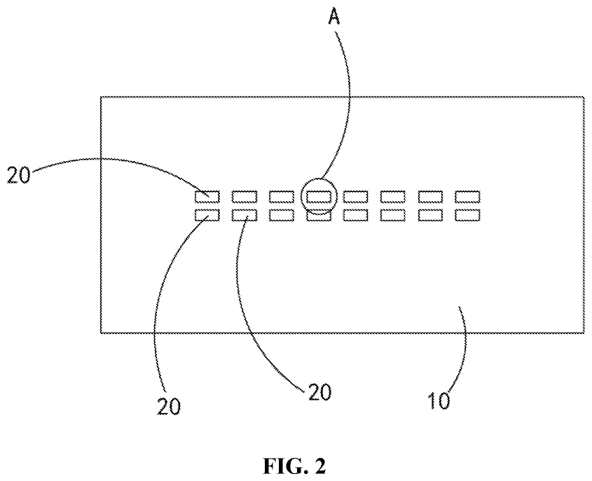

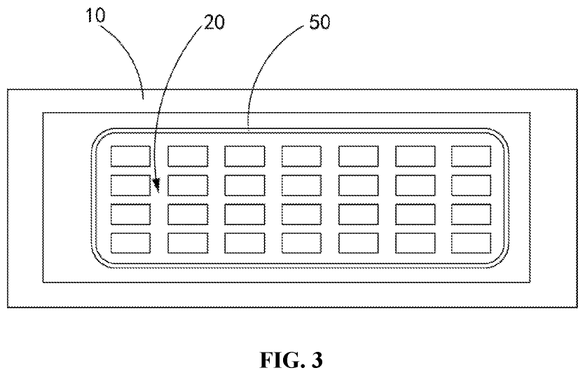

In an embodiment, as shown in FIG. 2, multiple fuse array groups 20 are formed in the semiconductor structure body 10, and the multiple fuse array groups 20 are arranged at intervals. FIG. 3 is an enlarged schematic structural diagram at a position A in FIG. 2. As shown in FIG. 3, a circumferential outer side of each fuse array group 20 is provided with a respective seal ring 50 for protection, and each fuse array group 20 may include multiple devices.

In an embodiment, multiple through holes 31 are formed in the shielding layer 30, and the multiple through holes 31 expose the multiple notches 11, respectively. That is, a respective sealing material layer 40 will be formed in each notch 11, and there will be no connection between the sealing material layers 40.

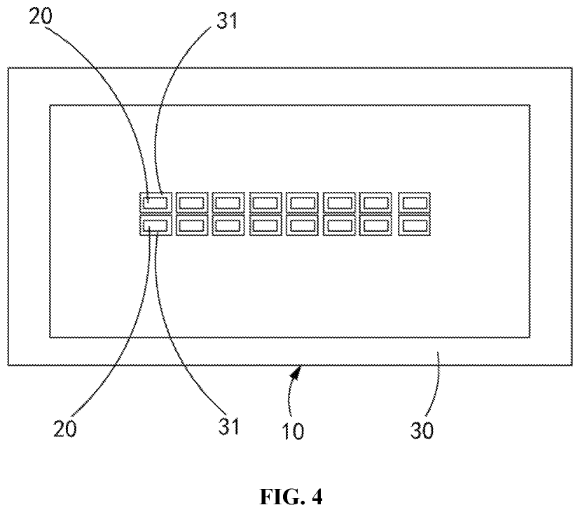

Specifically, on the basis of FIG. 2, the fused fuse array groups 20 are determined, that is, it is determined that the multiple notches 11 are formed in the semiconductor structure body 10. In this case, a corresponding number of through holes 31 are formed in the shielding layer 30 covering the semiconductor structure body 10. After the semiconductor structure body 10 is covered with the shielding layer 30, a structure as shown in FIG. 4 is formed. The multiple through holes 31 correspond to the multiple fuse array groups 20, respectively. That is, each through hole 31 corresponds to a respective notch 11. FIG. 4 shows that two fused fuse array groups 20 are arranged adjacent to each other. In some embodiments, an un-fused fuse array group 20 may be arranged between the two fused fuse array groups 20.

In an embodiment, one through hole 31 exposes the multiple notches 11. That is, an integral sealing material layer 40 is formed in respective notches 11.

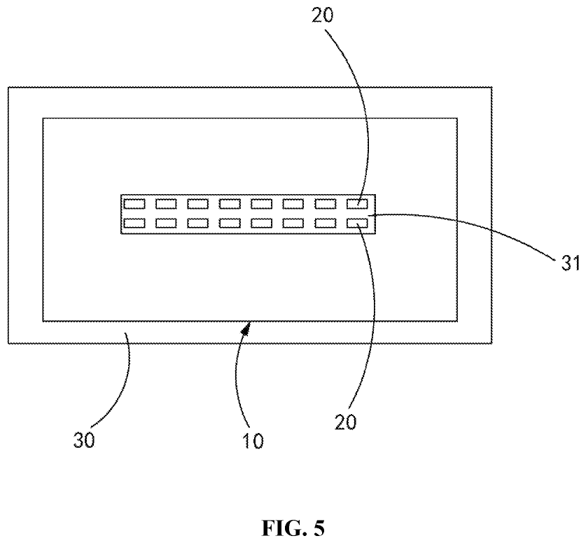

Specifically, on the basis of FIG. 2, the fused fuse array groups 20 are determined, that is, it is determined that the multiple notches 11 are formed in the semiconductor structure body 10. In this case, a large through hole 31 is formed in the shielding layer 30 covering the semiconductor structure body 10. The large through hole 31 may correspond to the multiple notches 11 at the same time, that is, the part of the semiconductor structure body 10 between the notches 11 may also be exposed. After the semiconductor structure body 10 is covered with the shielding layer 30, a structure as shown in FIG. 5 is formed. One through hole 31 corresponds to the multiple fuse array groups 20. That is, the one through hole 31 corresponds to the multiple notches 11. Subsequently, after the sealing material layer 40 is formed, the sealing material layer 40 is formed in the through hole 31, That is, a large piece of sealing material layer 40 fills the multiple notches 11.

It should be noted that when the multiple notches 11 are exposed by one through hole 31, the best embodiment is as follow. The multiple fused fuse array groups 20 are arranged adjacent to each other, so that the subsequent removal process of the sealing material layer 40 is not required, so as to improve the formation efficiency, avoid the subsequent use of etching process and the like, and prevent damage to the semiconductor structure body 10.

It should be noted that for the embodiments shown in FIG. 4 and FIG. 5, the difference is that FIG. 4 shows that one through hole 31 corresponds to one notch 11 while FIG. 5 shows that one through hole 31 corresponds to multiple notches 11.

In some embodiments, multiple through holes 31 are formed in the shielding layer 30. The multiple through holes 31 are arranged at intervals, and the sizes of the multiple through holes 31 may be different. That is, for some through holes 31 of the multiple through holes, each through hole corresponds to a respective notch 11; for some through hole 31 of the multiple through holes, each through hole corresponds to respective multiple notches 11.

In some embodiments, the specific formation of the corresponding notch 11 is not limited and may be determined by an actual fusing process, as long as it can be ensured that the interconnection structure 21 may be fused, that is, the corresponding fuse array group 20 is disconnected. Correspondingly, the specific shape of the through hole 31 is not limited and may be adaptively adjusted according to the shape of the notch 11, that is, to ensure that the notch 11 may be exposed.

In an embodiment, an area of the through hole 31 is larger than an area of the notch 11, so that the sealing material layer 40 covers a part of an upper surface of the semiconductor structure body 10. That is, on the basis of filling the notch 11, the sealing material layer 40 needs to cover a part of a plane where the opening of the notch 11 is located, that is, the top area of the formed sealing material layer 40 is larger than the opening area of the notch 11. In this way, reliable protection on the notch 11 is realized.

It is to be noted that the size of the top area of the sealing material layer 40 should not be too large so as to avoid covering some areas that should not be covered. It is only necessary to ensure that the opening of the notch 11 may be reliably covered. The size of the top area of the sealing material layer 40 is not limited here and may be determined according to the actual situation of the semiconductor structure.

In an embodiment, forming of the sealing material layer 40 may include that: an initial sealing material layer 41 is formed on the shielding layer 30, the initial sealing material layer 41 covers the shielding layer 30 and fills the notch 11 and the through hole 31; and the shielding layer 30 and a part, covering the shielding layer 30, of the initial sealing material layer 41 are removed, and a remaining part of the initial sealing material layer 41 is taken as the sealing material layer 40.

Specifically, after the semiconductor structure body 10 is covered with the shielding layer 30, the initial sealing material layer 41 needs to be formed on the shielding layer 30. In this case, the initial sealing material layer 41 may cover the entire shielding layer 30, that is, the entire shielding layer 30 is buried in the initial sealing material layer 41. Therefore, the part, covering the shielding layer 30, of the initial sealing material layer 41 needs to be removed later. Correspondingly, the shielding layer 30 also needs to be removed, and a part, protecting the notch 11, of the sealing material layer 40 is retained.

It should be noted that the initial sealing material layer 41 may be formed by adopting a Physical Vapor Deposition (PVD) process, a Chemical Vapor Deposition (CVD) process or an Atomic Layer Deposition (ALD) process or the like.

In an embodiment, the shielding layer 30 and the part, covering the shielding layer 30, of the initial sealing material layer 41 are removed synchronously. That is, the shielding layer 30 and the part, covering the shielding layer 30, of the initial sealing material layer 41 may be removed simultaneously in one operation.

In an embodiment, before the sealing material layer 40 is formed by curing, the part, covering the shielding layer 30, of the initial sealing material layer 41 is removed by removing the shielding layer 30. Since the initial sealing material layer 41 has not been cured yet and the material of the shielding layer 30 is relatively hard, the shielding layer 30 may be pulled to remove the shielding layer 30 and the part, covering the shielding layer 30, of the initial sealing material layer 41.

It should be noted that when the shielding layer 30 is pulled, since the initial sealing material layer 41 is not cured, the part, covering the shielding layer 30, of the initial sealing material layer 41 will be separated from a part, located in the notch 11 and the through hole 31, of the initial sealing material layer 41 under the action of force, so that it is achieved that only the part, covering the shielding layer 30, of the initial sealing material layer 41 may be removed, and it is ensured that the part, located in the notch 11 and the through hole 31, of the initial sealing material layer 41 will not be removed. Of course, it does not rule out that a part, located in the through hole 31, of the initial sealing material layer 41 will be partially removed, but it will not affect the overall protective effect of the initial sealing material layer 41 on the notch 11. The removal process is relatively simple, the operation process is also relatively simple, and the efficiency is relatively high.

In an embodiment, the part, covering the shielding layer 30, of the initial sealing material layer 41 is removed at first, and then the shielding layer 30 is removed. That is, the part, covering the shielding layer 30, of the initial sealing material layer 41 and the shielding layer 30 are removed successively, so as to ensure the accuracy of removal.

In an embodiment, before the part, covering the shielding layer 30, of the initial sealing material layer 41 is removed, the initial sealing material layer 41 is cured, so as to ensure that the initial sealing material layer 41 filled in the through hole 31 will not be removed by mistake.

It should be noted that the initial sealing material layer 41 is cured at first, and then a part of the initial sealing material layer 41 is removed, in this case, a remaining part of the initial sealing material layer 41 may reliably seal the notch 11. When the part of the initial sealing material layer 41 is removed later through etching process and the like, because the bottom of the part of the initial sealing material layer 41 is covered with the shielding layer 30, there will be no damage to the semiconductor structure body 10.

It should be noted that comparing the situation that the shielding layer 30 and the part, covering the shielding layer 30, of the initial sealing material layer 41 are removed synchronously before the initial sealing material layer 41 is cured with the situation that the part, covering the shielding layer 30, of the initial sealing material layer 41 and the shielding layer 30 are removed successively after the initial sealing material layer 41 is cured, the forming by synchronously removing the shielding layer 30 and the part, covering the shielding layer 30, of the initial sealing material layer 41 will have higher efficiency.

In an embodiment, forming of the shielding layer 30 may include that: a first positioning part in the shielding layer 30 is arranged opposite to a second positioning part in the semiconductor structure body 10, with the through hole 31 exposing the notch 11. That is, it is ensured that the through hole in the shielding layer 30 may accurately expose the corresponding notch 11.

It should be noted that the first positioning part is arranged opposite to the second positioning part, that is, the first positioning part and the second positioning part are aligned with each other. For example, the first positioning part and the second positioning part may be holes with the same structure, that is, it is ensured that the two holes coincide; or the first positioning part and the second positioning part may be protrusions with the same structure, that is, the two protrusions coincide; or the first positioning part and the second positioning part may be a protrusion and a groove respectively, and the protrusion matches with the groove.

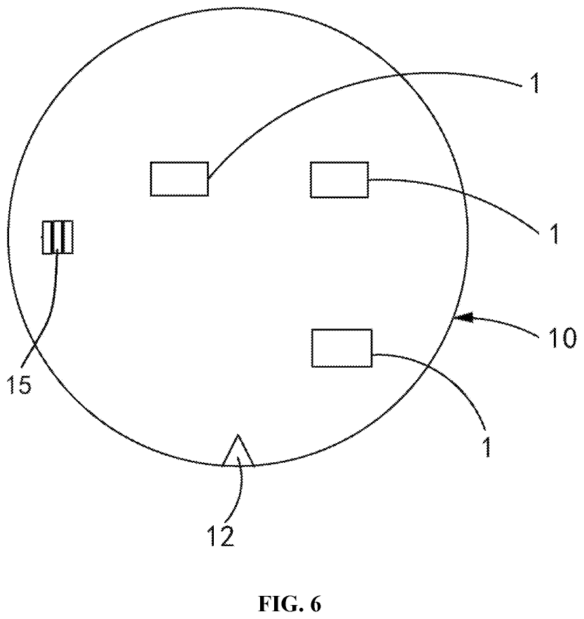

Specifically, as shown in FIG. 6, the semiconductor structure body 10 is provided with multiple dies 1, and the semiconductor structure body 10 is provided with the second positioning part which may be a wafer notch 12. The semiconductor structure body 10 may represent a wafer where the dies 1 are spread, each die 1 may include one or more fuse array groups 20, and the wafer may be circular or rectangular, which is not limited here.

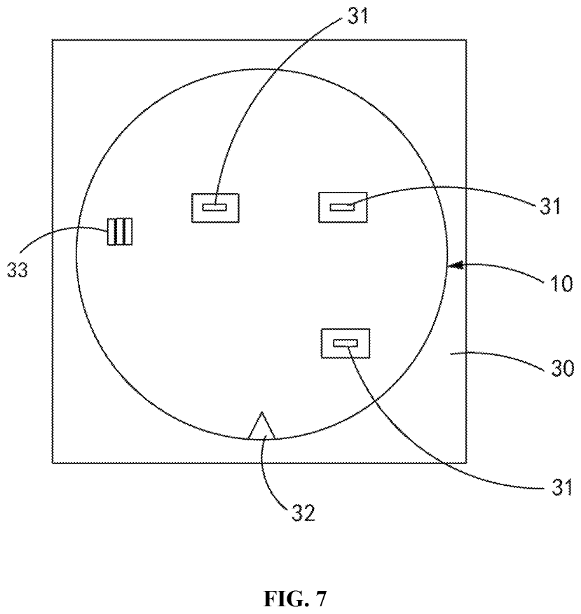

The first positioning part is formed in the shielding layer 30. On the basis of FIG. 6, the first positioning part is arranged opposite to the second positioning part, so as to realize the exposure of the notch 11 by the through hole 31. As shown in FIG. 7, the first positioning part may be a film positioning hole 32, and in this case, the film positioning hole may correspond to the wafer notch 12. Or, the first positioning part may be a film positioning identifier 33, and the second positioning part arranged in the semiconductor structure body 10 may be a corresponding wafer positioning identifier 15, and the film positioning identifier 33 corresponds to the wafer positioning identifier 15.

In some embodiments, the film positioning hole 32 and the film positioning identifier 33 may be formed in the shielding layer 30 while a corresponding wafer notch 12 and a corresponding wafer positioning identifier 15 may be formed in the semiconductor structure body 10. The film positioning hole 32 corresponds to the wafer notch 12, and the film positioning identifier 33 corresponds to the wafer positioning identifier 15, so as to realize the exposure of the notch 11 by the through hole 31.

The shielding layer 30 may be circular or rectangular, and is not specifically limited here. The shielding layer 30 may touch the surface of the wafer by means of simple pressing, or the shielding layer 30 may be fixed on the wafer by means of electrostatic or adhesive bonding. The first positioning part and the second positioning part are arranged opposite to each other, and the positioning adopts laser direct or indirect alignment. Thus, the structure shown in FIG. 7 is formed, that is, the through hole 31 may expose the die 1.

In an embodiment, the method for fusing and filling the semiconductor structure may further include that: the shielding layer 30 is removed; an outer surface of the sealing material layer 40 is cleaned. That is, after the shielding layer 30 is removed to form the sealing material layer 40, it is necessary to clean the sealing material layer 40 to remove residues on the surface, reduce the line width and reduce the coverage of other areas.

In some embodiments, cleaning of the outer surface of the sealing material layer 40 may include that: the sealing material layer 40 is thinned and a size of the sealing material layer 40 in a width direction is reduced. That is, after the shielding layer 30 is removed, the thickness and width of the sealing material layer 40 may be reduced, so as to avoid the problem that the sealing material layer 40 is too thick and the coverage is too large.

Specifically, the outer surface of the sealing material layer 40 is subjected to residue removal, trimming and cleaning.

The residue on the surface is removed by ashing (N2/H2/O2 or mixed gas) or etch trim, thereby reducing the line width, and reducing the coverage of other areas. Subsequently, the residue may be further removed by Ar sputter or wet clean (SPM+SC1+SC2 or special cleaning agent suitable for Al).

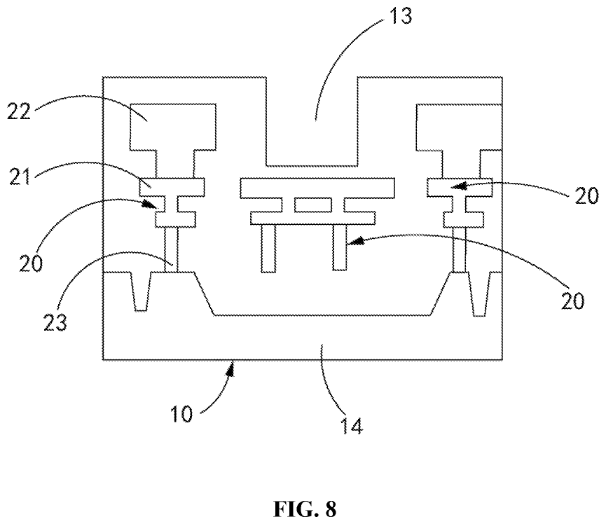

A specific embodiment of a method for fusing and filling a semiconductor structure is shown in FIG. 8 to FIG. 14.

As shown in FIG. 8, an opening 13 is formed in the semiconductor structure body 10, and the interconnection structure 21 of the fuse array group 20 is under the opening 13. The opening 13 may be formed in the following manner. A mask is formed on the semiconductor structure body 10, the mask covers an area outside the opening 13, and then the opening 13 may be formed by etching or laser fusing or the like.

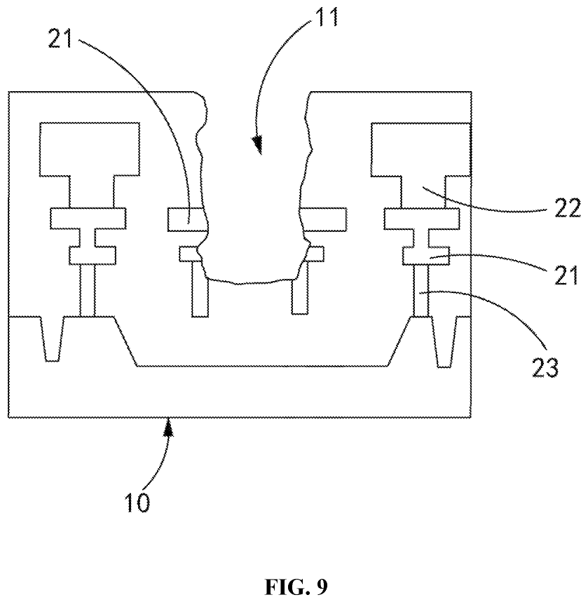

On the basis of FIG. 8, the interconnection structure 21 is fused by laser, and a notch 11 is formed on the basis of the opening 13, as shown in FIG. 9. In this case, the notch 11 is exposed to an external environment.

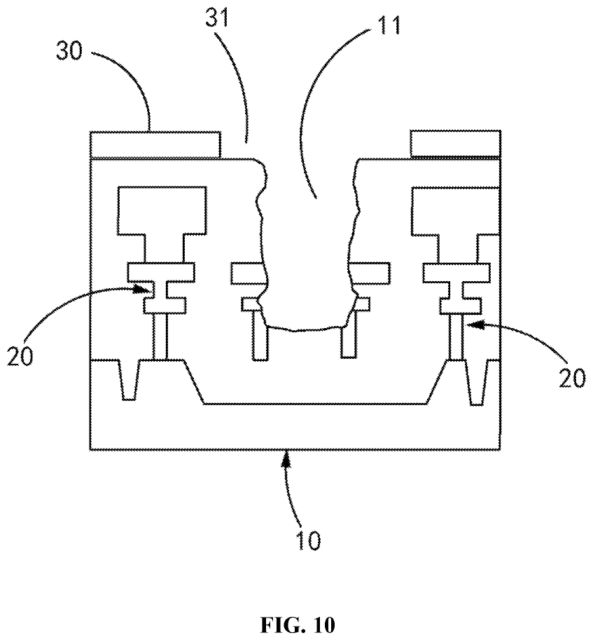

On the basis of FIG. 9, the semiconductor structure body 10 is covered with the shielding layer 30, and the through hole 31 in the shielding layer 30 exposes the notch 11, as shown in FIG. 10.

Specifically, the first positioning part in the shielding layer 30 and the second positioning part in the semiconductor structure body 10 can achieve the positioning by means of laser direct or indirect alignment. That is, the position of the through hole 31 is aligned with the position of the fuse array group 20, and the size of the through hole 31 may be determined according to the demand and influence of a required sealing area. If areas among the multiple fuse array groups 20 will not be affected by the sealing process, it may be considered to expand the through hole 31 throughout the whole fuse area to form a large opening, instead of multiple independent island structures.

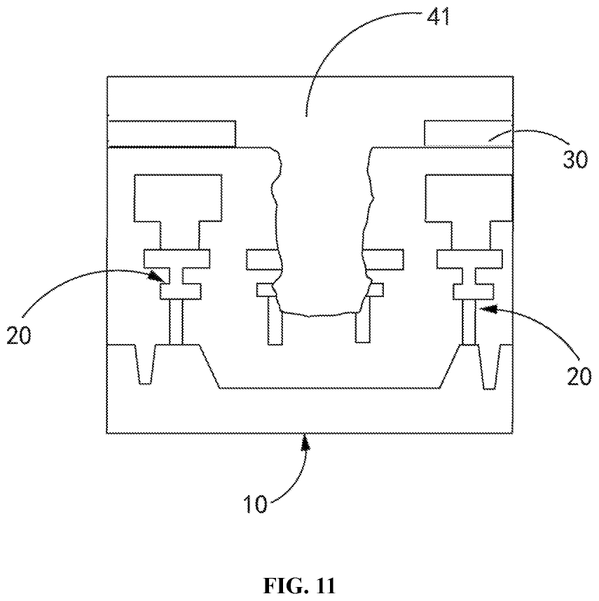

On the basis of FIG. 10, an initial sealing material layer 41 is formed on the shielding layer 30, as shown in FIG. 11, the initial sealing material layer 41 covers the shielding layer 30 and fills the through hole 31 and the notch 11.

Specifically, the initial sealing material layer 41 may be based on epoxy resin material or polyimide resin material or other resin materials that meet the requirements (expansion coefficient, adhesion strength and wettability with a target interface, chemical stability and compatibility, moisture resistance and isolation effect, anti-static degree, fluidity, degree of difficulty of coating, and/or the like). A brushing mode of the initial sealing material layer 41 may be a hard scraper scraping mode, a flexible material (PP, PVA . . . ) brush brushing mode, or a rotary spraying mode, and the specific process is not limited.

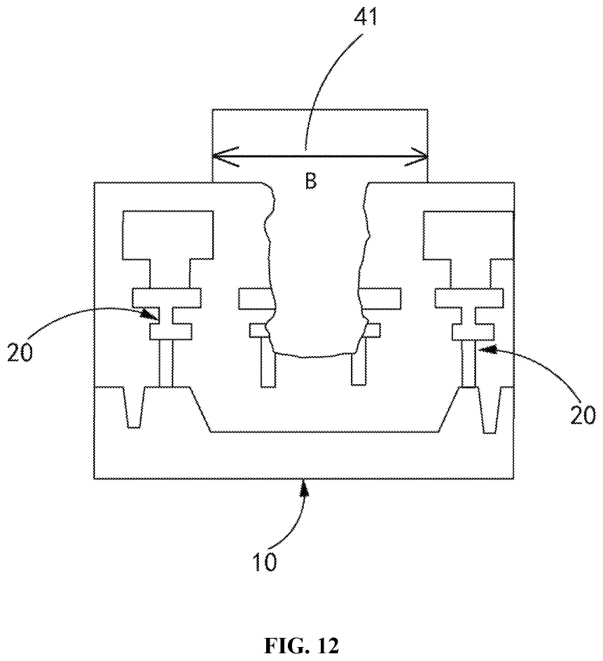

On the basis of FIG. 11, the shielding layer 30 and a part, covering the shielding layer 30, the initial sealing material layer 41 are removed to form a structure as shown in FIG. 12.

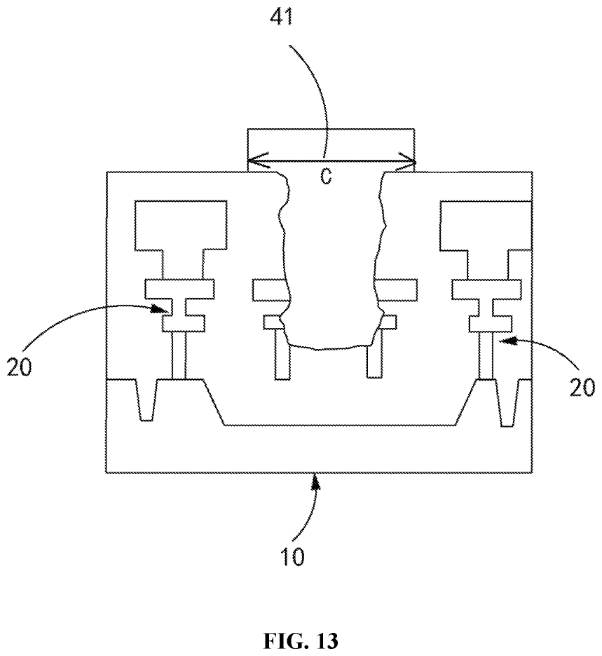

On the basis of FIG. 12, the residue on the surface is removed by ashing or etch trim, the line width is reduced (that is, the top width of the finally formed sealing material layer 40 becomes smaller), and the coverage of other areas by the initial sealing material layer 41 is reduced, as shown in FIG. 13. On the basis of FIG. 12, the line width of the initial sealing material layer 41 is B. After surface treatment, as shown in FIG. 13, the line width of the initial sealing material layer 41 is C, C is less than B, and the final line width of the sealing material layer 40 is C.

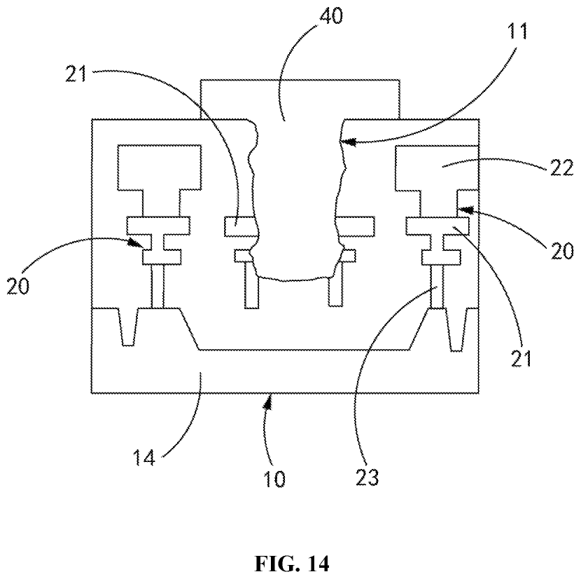

On the basis of FIG. 13, the initial sealing material layer 41 is thermally cured to form a sealing material layer 40, as shown in FIG. 14.

Specifically, the curing may be performed at 120° C.˜400° C. for 30 min-500 min, and the appropriate atmosphere, such as nitrogen, argon, water vapor or mixed gas, may be selected according to the material properties.

The semiconductor structure formed by the method for fusing and filling the semiconductor structure of the disclosure may isolate the intrusion of external risk factors.

An embodiment of the disclosure further provides a semiconductor structure. With reference to FIG. 14, the semiconductor structure includes a semiconductor structure body 10 and a sealing material layer 40. Multiple fuse array groups 20 are formed in the semiconductor structure body 10, at least one notch 11 is formed in the semiconductor structure body 10, and at least one of interconnection structures 21 of the fuse array groups 20 is fused. The sealing material layer 40 is located in the notch 11.

According to the semiconductor structure of an embodiment of the disclosure, by filling the sealing material layer 40 in the notch 11 of the semiconductor structure body 10, the invasion of external risk factors can be isolated, so as to improve the service performance of the semiconductor structure.

In an embodiment, the sealing material layer 40 is arranged to protrude out of the semiconductor structure body 10 to cover a part of an upper surface of the semiconductor structure body 10. That is, the top area of the sealing material layer 40 is larger than the opening area of the notch 11, so as to improve the protective performance.

In an embodiment, the semiconductor structure may further include multiple seal rings 50, and each of the fuse array groups 20 is located in a respective one of the seal rings 50. The seal rings 50 realize the protection of the respective fuse array groups 20.

In an embodiment, the semiconductor structure is formed by the method for fusing and filling the semiconductor structure described above.

After considering the specification and practicing the disclosure here, those skilled in the art will easily think about other implementation schemes of the disclosure. The disclosure aims to contain any variations, uses, or adaptations of the various embodiments, and these variations, uses, or adaptations follow general principles of the disclosure and may include common general knowledge or conventional technical means in the technical field, which is not disclosed by the disclosure. The specification and the exemplary implementations are only considered as examples, and the practical scope and spirit of the disclosure are pointed out by the appended claims.

It should be understood that the disclosure is not limited to the precise structures described above and shown in the drawings, and various modifications and variations may be made without departing from the scope thereof. The scope of the disclosure is only defined by the appended claims.

What is claimed is:

1. A method for fusing and filling a semiconductor structure, comprising:
providing a semiconductor structure body, a plurality of fuse array groups being formed in the semiconductor structure body;
fusing at least one of interconnection structures of the fuse array groups to form at least one notch in the semiconductor structure body;
forming a shielding layer on the semiconductor structure body, at least one through hole exposing the at least one notch being formed in the shielding layer; and
forming a sealing material layer in the notch.

2. The method for fusing and filling the semiconductor structure of claim 1, wherein the shielding layer is made of a hard material.

3. The method for fusing and filling the semiconductor structure of claim 1, wherein the shielding layer is made of a polymer material, ceramic or a metal material.

4. The method for fusing and filling the semiconductor structure of claim 1, wherein the plurality of fuse array groups are fused to form a plurality of independent notches in the semiconductor structure body.

5. The method for fusing and filling the semiconductor structure of claim 4, wherein a plurality of through holes are formed in the shielding layer, and the plurality of through holes expose the plurality of notches, respectively.

6. The method for fusing and filling the semiconductor structure of claim 4, wherein one through hole exposes the plurality of notches.

7. The method for fusing and filling the semiconductor structure of claim 1, wherein an area of the through hole is larger than an area of the notch, so that the sealing material layer covers a part of an upper surface of the semiconductor structure body.

8. The method for fusing and filling the semiconductor structure of claim 1, wherein forming the sealing material layer comprises:
forming an initial sealing material layer on the shielding layer, the initial sealing material layer covering the shielding layer and filling the notch and the through hole; and
removing the shielding layer and a part, covering the shielding layer, of the initial sealing material layer, and taking a remaining part of the initial sealing material layer as the sealing material layer.

9. The method for fusing and filling the semiconductor structure of claim 8, wherein the shielding layer and the part, covering the shielding layer, of the initial sealing material layer are synchronously removed.

10. The method for fusing and filling the semiconductor structure of claim 9, wherein before forming the sealing material layer through curing, the part, covering the shielding layer, of the initial sealing material layer is removed by removing the shielding layer.

11. The method for fusing and filling the semiconductor structure of claim 8, wherein the part, covering the shielding layer, of the initial sealing material layer is removed first, and then the shielding layer is removed.

12. The method for fusing and filling the semiconductor structure of claim 11, wherein the initial sealing material layer is cured before the part, covering the shielding layer, of the initial sealing material layer is removed.

13. The method for fusing and filling the semiconductor structure of claim 1, wherein forming the shielding layer comprises:
arranging a first positioning part in the shielding layer to be opposite to a second positioning part in the semiconductor structure body, with the through hole exposing the notch.

14. The method for fusing and filling the semiconductor structure of claim 1, further comprising:
removing the shielding layer; and
cleaning an outer surface of the sealing material layer.

15. The method for fusing and filling the semiconductor structure of claim 14, wherein cleaning the outer surface of the sealing material layer comprises:
thinning the sealing material layer.

16. The method for fusing and filling the semiconductor structure of claim 15, wherein cleaning the outer surface of the sealing material layer further comprises:
reducing a size of the sealing material layer in a width direction.

17. A semiconductor structure, comprising:
a semiconductor structure body, wherein a plurality of fuse array groups are formed in the semiconductor structure body, at least one notch is formed in the semiconductor structure body, and at least one of interconnection structures of the fuse array groups is fused; and
a sealing material layer, located in the notch.

18. The semiconductor structure of claim 17, wherein the sealing material layer is arranged to protrude out of the semiconductor structure body to cover a part of an upper surface of the semiconductor structure body.

19. The semiconductor structure of claim 17, further comprising:
a plurality of seal rings, wherein each of the fuse array groups is located in a respective one of the seal rings.

20. The semiconductor structure of claim 17, wherein each fuse array group further comprises a bonding pad and a contact hole, the interconnection structure of the fuse array group is connected to the bonding pad and the contact hole.
